(19) United States
(12) Patent Application Publication
(10) Pub. No.: US 2026/0260613 A1
(43) Pub. Date: Sep. 3, 2026

(54) LIGHT EMITTING DISPLAY APPARATUS

(71) Applicant: LG Display Co., Ltd., Seoul (KR)

(72) Inventors: JunHyeok YANG, Paju-si (KR); YongChan PARK, Paju-si (KR)

(21) Appl. No.: 19/423,636

(22) Filed: Dec. 17, 2025

(30) Foreign Application Priority Data
Feb. 28, 2025 (KR) 10-2025-0026409

(51) Int. Cl. G09G 3/3233

(52) U.S. Cl. CPC G09G 3/3233; G09G 2300/0842; G09G 2310/08; G09G 2320/045

(57) ABSTRACT

A light emitting display apparatus including a light emitting device, a first transistor including a first terminal electrically connected to a first terminal of the light emitting device, a second transistor electrically connected between a second terminal of the first transistor and a first voltage line to which a first voltage is supplied, a third transistor electrically connected between the second terminal of the first transistor and a data line to which a data voltage is supplied, a storage capacitor electrically connected between a gate of the first transistor and a line to which a light emission scan signal is supplied, and a fourth transistor including a first terminal electrically connected to the gate of the first transistor and a second terminal electrically connected to the first terminal of the light emitting device.

### CROSS REFERENCE TO RELATED APPLICATION

This application claims priority from and the benefit of Korean Patent Application No. 10-2025-0026409, filed on Feb. 28, 2025, which is hereby incorporated by reference for all purposes as if fully set forth herein

### BACKGROUND

### Field

Embodiments of the invention relate generally to an apparatus and, more particularly, to a light emitting display apparatus.

### Discussion of the Background

Light emitting display apparatuses are mounted on or provided in electronic products such as televisions, monitors, notebook computers, smart phones, tablet computers, electronic pads, wearable devices, smart watch, portable information devices, navigation devices, or vehicle control display devices, etc., to display images. Pixels are provided in a light emitting display panel configuring a light emitting display apparatus, and a light emitting device is provided in each of the pixels.

When a threshold voltage of a driving transistor changes due to various causes, light with a luminance corresponding to a data voltage is not output from a light emitting device. In order to solve this problem, a large number of transistors are provided in a pixel driving circuit.

However, it is well-known that as the number of transistors increases, the number of pixels that may be provided in a certain area decreases, making it difficult to implement a high-resolution light emitting display apparatus.

The above information disclosed in this Background section is only for understanding of the background of the inventive concepts, and, therefore, it may contain information that does not constitute prior art.

### SUMMARY

A light emitting display apparatus according to embodiments of the invention is capable of compensating for threshold voltage variations of a driving transistor by using four transistors.

Additional features of the inventive concepts will be set forth in the description which follows, and in part will be apparent from the description, or may be learned by practice of the inventive concepts.

According to one or more embodiments of the invention, a light emitting display apparatus includes: a light emitting device; a first transistor including a first terminal electrically connected to a first terminal of the light emitting device; a second transistor electrically connected between a second terminal of the first transistor and a first voltage line to which a first voltage is supplied; a third transistor electrically connected between the second terminal of the first transistor and a data line to which a data voltage is supplied; a storage capacitor electrically connected between a gate of the first transistor and a line to which a light emission scan signal is supplied; and a fourth transistor including a first terminal electrically connected to the gate of the first transistor and a second terminal electrically connected to the first terminal of the light emitting device.

The types of the second and third transistor may be different from each other.

Each of the first transistor, the third transistor, and the fourth transistor may be an N-type transistor, and the second transistor may be a P-type transistor.

A current flowing through the light emitting device may be proportional to a square of a voltage obtained by subtracting a threshold voltage of the light emitting device from the data voltage.

The gate of the second transistor and the gate of the third transistor may be electrically connected to each other.

A power scan signal supplied to a gate of the second transistor, a data scan signal supplied to a gate of the third transistor, and a compensation scan signal supplied to a gate of the fourth transistor may be the same signals.

In a compensation and writing period during which a threshold voltage of the first transistor and the data voltage are charged in a gate of the first transistor, a phase of the power scan signal may be opposite to a phase of a light emission scan signal supplied to a first terminal of the storage capacitor.

In a light emitting period during which light is emitted from the light emitting device, a phase of the power scan signal may be opposite to a phase of the light emission scan signal.

During a holding period between the compensation and writing period and the light emitting period, a phase of the power scan signal and a phase of the light emission scan signal may be the same.

A gate of the second transistor and a gate of the third transistor may not be electrically connected to each other.

A data scan signal supplied to a gate of the third transistor and a compensation scan signal supplied to a gate of the fourth transistor may be the same signals.

In a compensation and writing period during which a threshold voltage of the first transistor and the data voltage are charged in a gate of the first transistor, a phase of a power scan signal supplied to a gate of the second transistor may be the same as that of the data scan signal, and a phase of the power scan signal may be opposite to a phase of a light emission scan signal supplied to a first terminal of the storage capacitor.

In a light emitting period during which light is output from the light emitting device, a phase of the power scan signal and a phase of the data scan signal may be opposite to a phase of the light emission scan signal.

In a holding period between the compensation and writing period and the light emitting period, a phase of the data scan signal and a phase of the light emission scan signal may be the same.

When the compensation and writing period begins, the second transistor may be turned off by the power scan signal, and after a predetermined period elapses, the third transistor may be turned on by the data scan signal.

When the compensation and writing period ends, the third transistor may be turned off by the data scan signal, and after a predetermined period elapses, the second transistor may be turned on by the power scan signal.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a diagram illustrating a configuration of a light emitting display apparatus according to an embodiment of the invention.

FIG. 2 is a circuit diagram illustrating a structure of a pixel applied to a light emitting display apparatus according to an embodiment of the invention.

FIG. 3 is timing diagram illustrating scan signals applied to a light emitting display apparatus including the pixel illustrated in FIG. 2.

FIG. 4 is circuit diagram illustrating a method of driving a pixel in a previous frame period A0 illustrated in FIG. 3.

FIG. 5 is circuit diagram illustrating a method of driving a pixel in a compensation and writing period A1 illustrated in FIG. 3.

FIG. 6 is a circuit diagram illustrating a method of driving a pixel in a holding period A2 illustrated in FIG. 3.

FIG. 7 is a circuit diagram illustrating a method of driving a pixel in a light emitting period A3 illustrated in FIG. 3.

FIG. 8 is another circuit diagram illustrating a structure of a pixel applied to a light emitting display apparatus according to an embodiment of the invention.

FIG. 9 is a timing diagram illustrating scan signals applied to a light emitting display apparatus including the pixel illustrated in FIG. 8.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

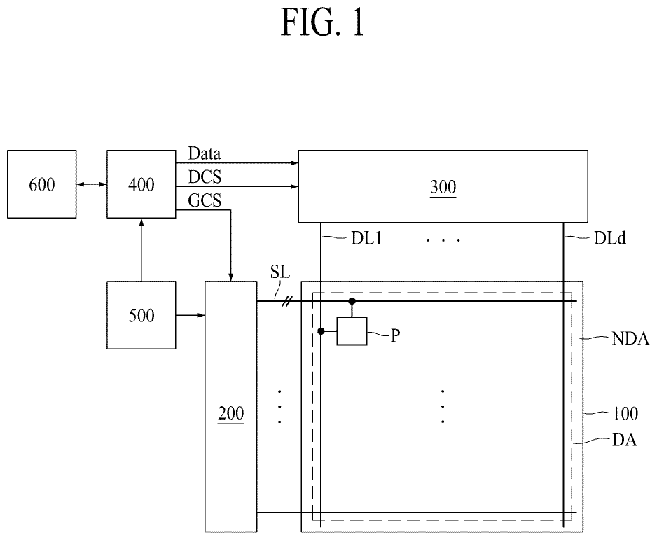

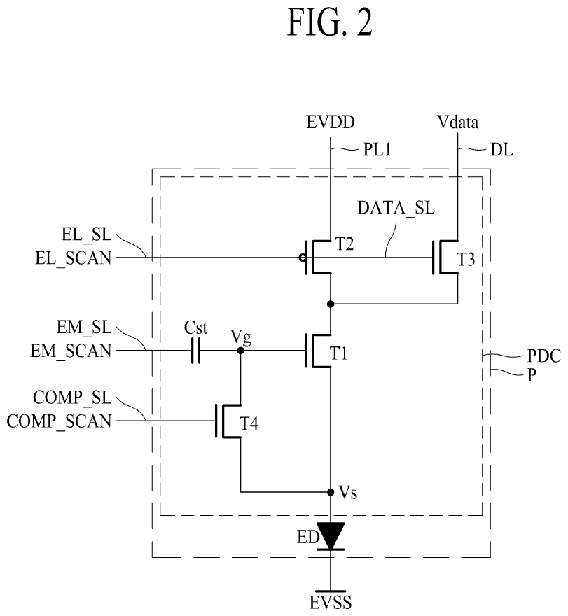

FIG. 1 is a diagram illustrating a configuration of a light emitting display apparatus according to an embodiment of the invention, and FIG. 2 is a circuit diagram illustrating a structure of a pixel applied to a light emitting display apparatus according to an embodiment of the invention.

A light emitting display apparatus according to an embodiment of the invention may be used in various kinds of electronic devices. Electronic devices may be, for example, televisions, monitors, etc.

The light emitting display apparatus according to an embodiment of the invention, as illustrated in FIGS. 1 and 2, may include a light emitting display panel 100 which includes a display area DA displaying an image and a non-display area NDA provided outside the display area DA, a gate driver 200 which supplies scan signals to a plurality of scan lines SL provided in the display area DA of the display panel 100, a data driver 300 which supplies data voltages Vdata to a plurality of data lines DL1 to DLd provided in the display area DA of the display panel 100, a control unit 400 which controls driving of the gate driver 200 and the data driver 300, and a power supply unit 500 which supplies power to the control unit 400, the gate driver 200, the data driver 300, and the light emitting display panel 100.

First, the light emitting display panel 100 may include a display area DA and a non-display area NDA. Scan lines SL, data lines DL1 to DLd, and pixels P may be provided in the display area DA. Here, d is a natural number. Accordingly, an image may be displayed in the display area DA. The non-display area NDA may surround the outer periphery of the display area DA.

The pixel P included in the light emitting display panel 100, as illustrated in FIG. 2, may include a pixel driving circuit PDC, which includes four transistors T1 to T4 and a storage capacitor Cst, and a light emitting device ED electrically connected to the pixel driving circuit PDC.

A first transistor T1 may be a driving transistor. The driving transistor may perform a function of controlling the magnitude of the current supplied to the light emitting device ED depending on the magnitude of the data voltage Vdata supplied through the data line DL. A first terminal of the first transistor T1 is electrically connected to a first terminal of the light emitting device ED, a second terminal of the first transistor T1 is electrically connected to a first terminal of a second transistor T2 and a first terminal of a third transistor T3, and a gate of the first transistor T1 may be electrically connected to a second terminal of the storage capacitor Cst.

The first terminal of the second transistor T2 may be electrically connected to the second terminal of the first transistor T1, a second terminal of the second transistor T2 may be electrically connected to a first voltage line PL1 to which the first voltage EVDD is supplied, and a gate of the second transistor T2 may be electrically connected to the power scan line EL_SL to which a power scan signal EL_SCAN is supplied.

The first terminal of the third transistor T3 may be electrically connected to the second terminal of the first transistor T1, a second terminal of the third transistor T3 may be electrically connected to a data line DL, and a gate of the third transistor T3 may be electrically connected to a data scan line DATA_SL.

A first terminal of the storage capacitor Cst may be electrically connected to a light emission scan line EM_SL, to which a light emission scan signal EM_SCAN is supplied, and a second terminal of the storage capacitor Cst may be electrically connected to the gate of the first transistor T. For example, the storage capacitor Cst may be electrically connected between the gate of the first transistor T1 and the light emission scan line EM_SL to which the light emission scan signal EM_SCAN is supplied.

A first terminal of a fourth transistor T4 may be electrically connected to the gate of the first transistor T1, a second terminal of the fourth transistor T4 may be electrically connected to the first terminal of the light emitting device, and a gate of the fourth transistor T4 may be electrically connected to a compensation scan line COMP_SL to which a compensation scan signal COMP_SCAN is supplied.

In this case, the type of the second transistor T2 and the type of the third transistor T3 are different from each other.

For example, as illustrated in FIG. 2, each of the first transistor T1, the third transistor T3, and the fourth transistor T4 can be an N-type transistor, and the second transistor T2 can be a P-type transistor.

In this case, each of the first transistor T1, the third transistor T3, and the fourth transistor T4 may be an oxide thin film transistor, and the second transistor T2 may be a low-temperature polysilicon thin film transistor (LTPS TFT).

The light emitting device ED may include a first electrode receiving a first voltage EVDD through the second transistor T2 and the first transistor T1, a second electrode electrically connected to a line to which a second voltage EVSS is supplied, and a light emitting layer provided between the first electrode and the second electrode. The first electrode may be an anode, and the second electrode may be a cathode. The first electrode may be electrically connected to the first terminal of the first transistor T1 and the second terminal of the fourth transistor T4.

When the pixel driving circuit PDC is formed with the structure illustrated in FIG. 2, the magnitude of the current flowing to the light emitting device ED may be proportional to the square of the voltage obtained by subtracting the threshold voltage of the light emitting device ED from the data voltage Vdata.

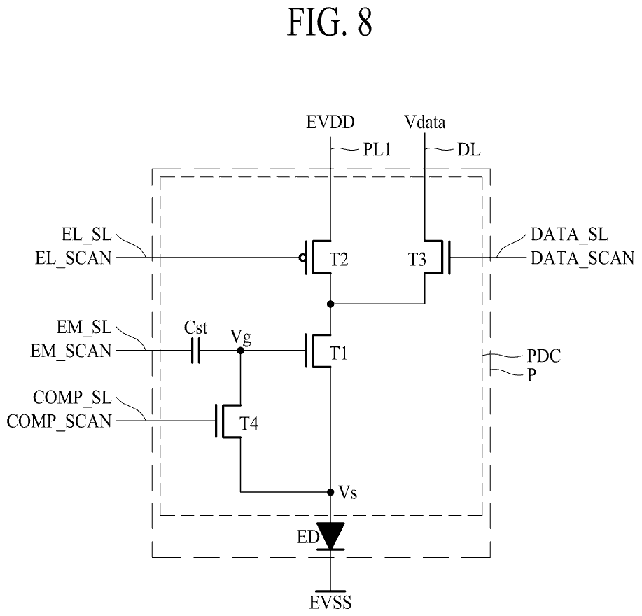

The structure of the pixel P applied to a light emitting display apparatus according to an embodiment of the invention is not limited to the structure illustrated in FIG. 2. Another structure of the pixel P applied to a light emitting display apparatus according to an embodiment of the invention will be described below with reference to FIG. 8.

The control unit 400 may realign input data signals transmitted from an external system 600 by using a timing synchronization signal transmitted from the external system and may generate a data control signal DCS which is to be supplied to the data driver 300 and a gate control signal GCS, which is to be supplied to the gate driver 200.

To this end, the control unit 400 may include a data aligner which realigns input data signals to generate data signals Data, a control signal generator which generates the gate control signal GCS and the data control signal DCS by using the timing synchronization signal, an input unit which transmits the timing synchronization signal transmitted from the external system 600 to the control signal generator and transmits the input data signals transmitted from the external system 600 to the data aligner, and an output unit which supplies the data driver 300 with the data signal Data generated by the data aligner and the data control signal DCS generated by the control signal generator and supplies the gate driver 200 with the gate control signal GCS generated by the control signal generator.

The control signal generator may generate a power control signal supplied to the power supply unit 500.

The external system 600 may perform a function of driving the control unit 400 and an electronic device.

For example, when the electronic device is a television (TV), the external system 600 may receive various kinds of sound information and image information over a communication network and may transmit the received image information to the control unit 400. For example, the external system 600 may convert the image information into input data signals and transmit the input data signals to the control unit 400.

The power supply unit 500 may generate various power levels, and supply the generated power levels to the control unit 400, the gate driver 200, the data driver 300, and the light emitting display panel 100.

The data driver 300 may supply data voltages Vdata to the data lines DL1 to DLd.

To this end, the data driver 300 may include a shift register which outputs a sampling signal, a latch which latches data signals Data received from the control unit 400, a digital-to-analog converter which converts the data signal Data, transmitted from the latch, into a data voltage Vdata and outputs the data voltage Vdata, and an output buffer which outputs the data voltage, transmitted from the digital-to-analog converter, to the data line DL based on a source output enable signal.

The shift register may output the sampling signal by using the data control signal DCS received from the control signal generator. For example, the data control signals DCS transmitted to the shift register may include a source start pulse and a source shift clock signal.

The latch may latch data signals Data sequentially received from the control unit 400, and then output the data signals Data to the digital-to-analog converter at the same time based on the sampling signal.

The digital-to-analog converter may convert the data signals Data transmitted from the latch into data voltages Vdata and output the data voltages Vdata.

The output buffer may simultaneously output the data voltages Vdata transmitted from the digital-to-analog converter to data lines DL1 to DLd of the light emitting display panel 100 based on the source output enable signal transmitted from the control signal generator.

To this end, the output buffer may include a buffer which stores the data voltage Vdata transmitted from the digital-to-analog converter and a switch which outputs the data voltage Vdata stored in the buffer to the data line DL based on the source output enable signal.

For example, when the switches are turned on based on the source output enable signal simultaneously supplied to the switches, the data voltages Vdata stored in the buffers may be supplied to the data lines DL1 to DLd through the switches.

The data voltages Vdata supplied to the data lines DL1 to DLd may be supplied to pixels P electrically connected to a gate line GL supplied with a gate pulse GP (not shown).

Finally, the gate driver 200 may be directly embedded into the non-display area NDA by using a gate-in panel (GIP) type, or the gate driver 200 may be provided in the display area DA in which light emitting devices ED are provided, or the gate driver 200 may be provided on a chip-on-film mounted in the non-display area NDA.

The gate driver 200 may supply scan signals EL_SCAN, EM_SCAN, and COMP_SCAN to the scan lines EL_SL, EM_SL, and COMP_SL.

In order to supply the scan signals EL_SCAN, EM_SCAN, and COMP_SCAN to the pixel P, the gate driver 200 may include stages electrically connected to the scan lines EL_SL, EM_SL, and COMP_SL.

Each of the stages may be electrically connected to at least one of the scan lines EL_SL, EM_SL, and COMP_SL.

At least one of the stages may be driven by a start signal transmitted from the control unit 400 to generate at least one of the scan signals EL_SCAN, EM_SCAN, and COMP_SCAN, and the other stages can be driven by a start signal transmitted from a previous stage to generate at least one of the scan signals EL_SCAN, EM_SCAN, and COMP_SCAN.

For example, in a stage, only one of the scan signals EL_SCAN, EM_SCAN, COMP_SCAN can be output, two scan signals can be output, three scan signals can be output, or all four scan signals can be output.

Hereinafter, a method of driving a light emitting display apparatus including the pixel P illustrated in FIG. 2 will be described with reference to FIGS. 1 to 7.

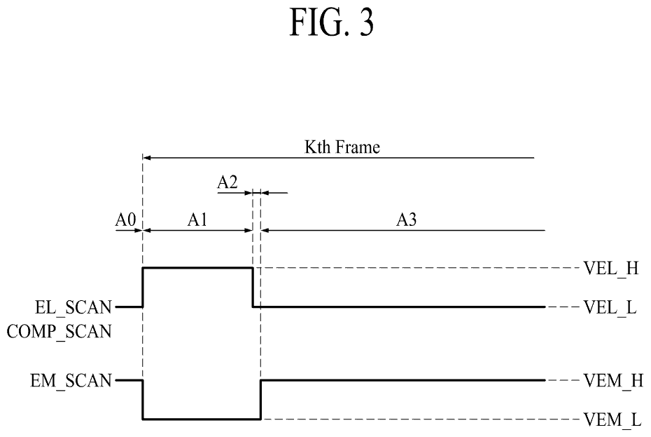

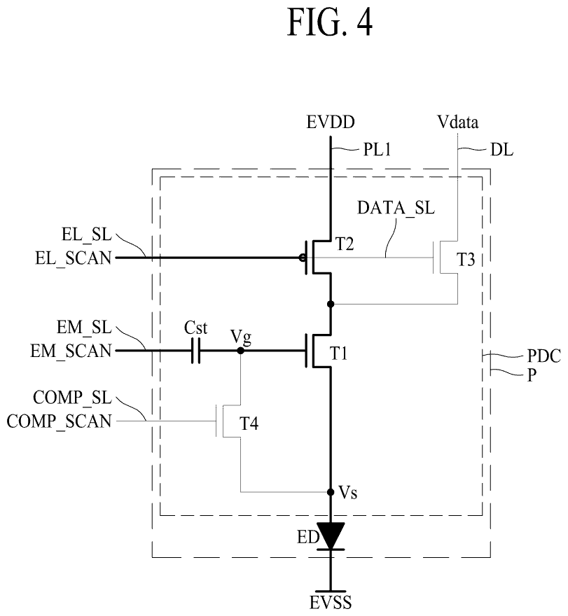

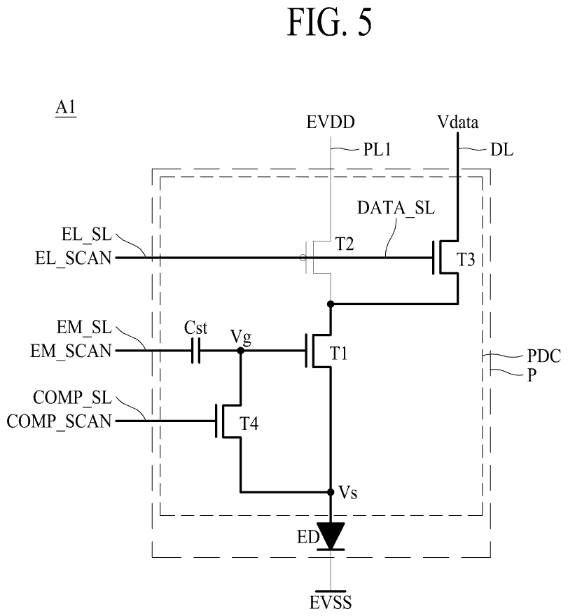

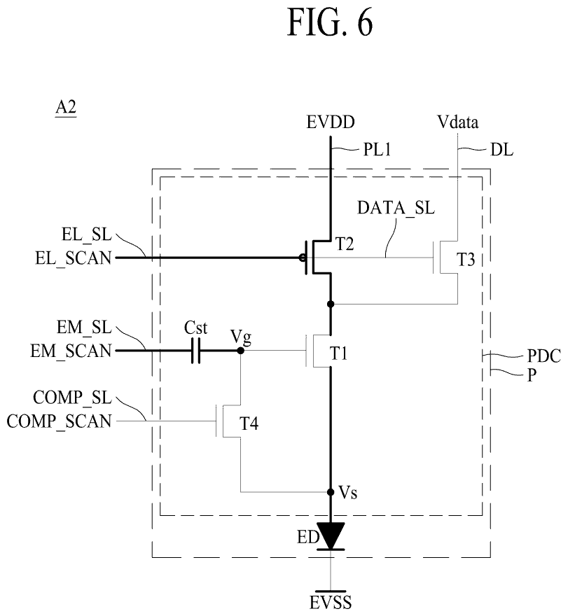

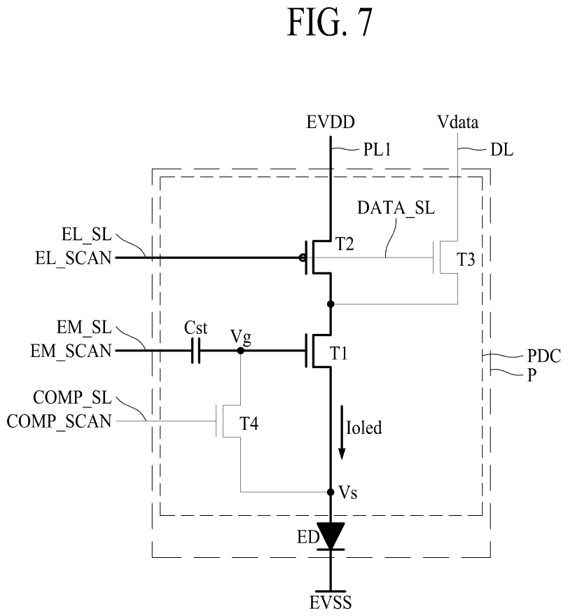

FIG. 3 is a timing diagram illustrating scan signals applied to a light emitting display apparatus including the pixel illustrated in FIG. 2; FIG. 4 is a circuit diagram illustrating a method of driving a pixel in a previous frame period A0 illustrated in FIG. 3; FIG. 5 is a circuit diagram illustrating a method of driving a pixel in a compensation and writing period A1 illustrated in FIG. 3; FIG. 6 is a circuit diagram illustrating a method of driving a pixel in a holding period A2 illustrated in FIG. 3; and FIG. 7 is a circuit diagram illustrating a method of driving a pixel in a light emitting period A3 illustrated in FIG. 3. In particular, FIGS. 3 to 7 illustrate a method of driving a pixel in a kth frame.

In the pixel P described above with reference to FIG. 2, the gate of the second transistor T2 and the gate of the third transistor T3 are electrically connected.

In this case, the power scan signal EL_SCAN supplied to the gate of the second transistor T2, the data scan signal supplied to the gate of the third transistor T3, and the compensation scan signal COMP_SCAN supplied to the gate of the fourth transistor T4 are the same signals.

Therefore, hereinafter, for convenience of description, the data scan signal supplied to the gate of the third transistor T3 is referred to as a “power scan signal EL_SCAN”.

First, in the previous frame period A0, light having a luminance corresponding to the data voltage Vdata supplied from the (k−1)th frame is output from the light emitting device ED.

In the previous frame period A0, as illustrated in FIG. 4, a low-level power scan signal EL_SCAN is supplied to the gate of the second transistor T2 and the gate of the third transistor T3, a low-level compensation scan signal COMP_SCAN is supplied to the gate of the fourth transistor T4, and the high-level light emission scan signal EM_SCAN is supplied to the first terminal of the storage capacitor Cst.

Accordingly, as illustrated in FIGS. 3 and 4, the first transistor T1 and the second transistor T2 are turned on, and the third transistor T3 and the fourth transistor T4 are turned off.

Therefore, in the previous frame period A0, a current corresponding to the data voltage Vdata supplied in the (k−1)th frame is supplied to the light emitting device ED, and accordingly, light can be output from the light emitting device ED.

In this case, the gate voltage Vg of the first transistor T1 may include the data voltage Vdata supplied in the (k−1)th frame.

Next, when the kth frame begins, the compensation and writing period A1 begins.

During the compensation and writing period A1, a threshold voltage of the first transistor T1 is compensated, and the data voltage Vdata may be charged in the gate of the first transistor T1.

Here, compensating the threshold voltage of the first transistor T1 may mean that the threshold voltage of the first transistor T1 is charged in the gate of the first transistor T1.

To this end, during the compensation and writing period A1 shown in FIG. 3, the power scan signal EL_SCAN having a high level VEL_H is supplied to the gate of the second transistor T2 and the gate of the third transistor T3, the compensation scan signal COMP_SCAN having a high level VEL_H is supplied to the gate of the fourth transistor T4, and the light emission scan signal EM_SCAN having the low level VEM_L is supplied to the first terminal of the storage capacitor Cst.

Accordingly, as illustrated in FIGS. 3 and 5, the first transistor T1, the third transistor T3, and the fourth transistor T4 are turned on, and the second transistor T2 is turned off.

Accordingly, the data voltage Vdata supplied through the data line DL may be charged in the gates of the first transistor T1 through the third transistor T3, the first transistor T1, and the fourth transistor T4.

In this case, the gate of the first transistor T1 may be charged with a voltage obtained by subtracting the high level VEM_H of the light emission scan signal EM_SCAN from the sum of the threshold voltage of the first transistor T1 and the data voltage Vdata supplied to the gate of the first transistor T1 through the third transistor T3, the first transistor T1, and the fourth transistor T4.

Because the gate of the first transistor T1 and the first terminal (hereinafter, simply referred to as a “source”) of the first transistor T1 are connected through the fourth transistor T4, the source voltage Vs of the first transistor T1 may be the same as the gate voltage Vg of the first transistor T1.

In the compensation and writing period A1 during which the threshold voltage of the first transistor T1 and the data voltage Vdat are charged in the gate of the first transistor T1, the phase of the power scan signal EL_SCAN may be opposite to that of the light emission scan signal EM_SCAN supplied to the first terminal of the storage capacitor Cst, as illustrated in FIG. 3.

In addition, because the power scan signal EL_SCAN and the compensation scan signal COMP_SCAN are the same signal, the phase of the compensation scan signal COMP_SCAN may be opposite to the phase of the light emission scan signal EM_SCAN supplied to the first terminal of the storage capacitor Cst, as illustrated in FIG. 3.

Next, the holding period A2 of the kth frame begins.

In the holding period A2, the power scan signal EL_SCAN having the low level VEL_L is supplied to the gate of the second transistor T2 and the gate of the third transistor T3, the compensation scan signal COMP_SCAN having the low level VEL_L is supplied to the gate of the fourth transistor T4, and the light emission scan signal EM_SCAN having the low level VEM_L is supplied to the first terminal of the storage capacitor Cst.

Accordingly, as illustrated in FIG. 6, the second transistor T2 is turned on, and the first transistor T1, the third transistor T3, and the fourth transistor T4 are turned off.

Therefore, in the holding period A2, the voltage charged in the gate of the first transistor T1 in the compensation and writing period A1 may be maintained.

For example, in the holding period A2, each of the gate voltage Vg and the source voltage Vs of the first transistor T1 can be a voltage obtained by subtracting the high level VEM_H of the light emission scan signal EM_SCAN from the sum of the threshold voltage of the first transistor T1 and the data voltage Vdata supplied to the gate of the first transistor T1 through the third transistor T3, the first transistor T1, and the fourth transistor T4.

In the holding period A2 between the compensation and writing period A1 and the light emitting period A3, the phase of the power scan signal EL_SCAN and the phase of the light emission scan signal EM_SCAN may be the same.

In addition, because the power scan signal EL_SCAN and the compensation scan signal COMP_SCAN are the same signal, the phase of the compensation scan signal COMP_SCAN may be the same as the phase of the light emission scan signal EM_SCAN, as illustrated in FIG. 3.

Finally, the light emitting period A3 of the kth frame begins.

In the light emitting period A3, the power scan signal EL_SCAN having the low level VEL_L is supplied to the gate of the second transistor T2 and the gate of the third transistor T3, the compensation scan signal COMP_SCAN having the low level VEL_L is supplied to the gate of the fourth transistor T4, and the light emission scan signal EM_SCAN having the high level VEM_H is supplied to the first terminal of the storage capacitor Cst.

Accordingly, as illustrated in FIG. 7, the first transistor T1 and the second transistor T2 are turned on, and the third transistor T3 and the fourth transistor T4 are turned off.

In this case, the high level VEM_H of the light emission scan signal EM_SCAN can be supplied to the gate of the first transistor T1.

Accordingly, a gate voltage Vg of the first transistor T1 during the light emitting period A3 may be the sum of the data voltage Vdata and the threshold voltage of the first transistor T1.

In the light emitting period A3, a source voltage Vs of the first transistor T1 may be the threshold voltage Voled of the light emitting device ED.

In the light emission period A3, a current Ioled flowing through the light emitting device ED may be proportional to the square of a voltage obtained by subtracting the threshold voltage Vth of the first transistor T1 from a voltage obtained by subtracting the source voltage Vs from the gate voltage Vg of the first transistor T1 (hereinafter simply referred to as a “gate-source voltage Vgs”), as expressed in [Equation 1].

$$Ioled = {k ( Vgs - Vth )}^{2} \qquad [ Equation 1 ]$$

In [Equation 1], k may be a constant in consideration of the mobility, the width of the channel, and the length of the channel of the driving transistor Tdr, and the like.

In the above example, the gate-source voltage Vgs of the driving transistor Tdr may be represented by [Equation 2] below.

$$Vgs = Vdata + Vth - Voled \qquad [ Equation 2 ]$$

In this case, the gate-source voltage Vgs of the first transistor T1 may be a voltage obtained by subtracting the threshold voltage Voled of the light emitting device ED from the sum of the data voltage Vdata and the threshold voltage Vth of the first transistor T1.

Therefore, a voltage obtained by subtracting the threshold voltage Vth of the first transistor T1 from the gate-source voltage Vgs of the first transistor T1 may be expressed as [Equation 3].

$$Vgs - Vth = Vdata - Voled \qquad [ Equation 3 ]$$

Accordingly, based on [Equation 1] to [Equation 3], the current Ioled flowing to the light emitting device ED during the light emitting period A3 may be proportional to the square of the difference voltage between the data voltage Vdata and the threshold voltage Voled of the light emitting device ED.

Therefore, when it is assumed that the threshold voltage Voled of the light emitting device ED is constant, according to the light emitting display apparatus according to an embodiment of the invention, the magnitude of the current Ioled flowing to the light emitting device ED is not related to the threshold voltage Vth of the first transistor T1 and may be determined by the data voltage Vdata.

The luminance of light output from the light emitting device ED may be determined by the magnitude of a current Ioled flowing through the light emitting device ED.

Therefore, even if the light emitting display apparatus according to an embodiment of the invention is used for a long time and the first transistor T1 is deteriorated, the luminance of light output from the light emitting device ED may be changed only by the data voltage Vdata, and is not affected by the threshold voltage Vth of the first transistor T1.

Accordingly, according to the light emitting display apparatus according to an embodiment of the invention, the quality of the light emitting display apparatus may be maintained for a long time.

In the light emitting period A3 in which light is output from the light emitting device ED, the phase of the power scan signal EL_SCAN may be opposite to the phase of the light emission scan signal EM_SCAN.

Also, because the power scan signal EL_SCAN and the compensation scan signal COMP_SCAN are the same signal, the phase of the compensation scan signal COMP_SCAN may be opposite to the phase of the light emission scan signal EM_SCAN in the light emission period A3, as illustrated in FIG. 3.

According to the pixel P described above, because the gate of the second transistor T2 and the gate of the third transistor T3 are electrically connected to each other, the light emitting display panel 100 may be provided with one scan line SL electrically connected to the gate of the second transistor T2 and the gate of the third transistor T3.

Accordingly, the manufacturing process of the light emitting display panel 100 may be simplified, and as the area of the scan line is reduced, the light emitting area may be increased.

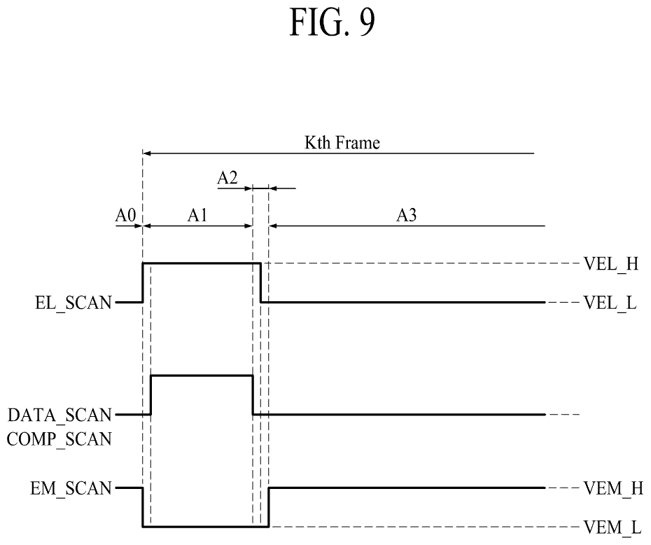

FIG. 8 is another circuit diagram illustrating a structure of a pixel applied to a light emitting display apparatus according to an embodiment of the invention, and FIG. 9 is a timing diagram illustrating scan signals applied to a light emitting display apparatus including the pixel illustrated in FIG. 8.

As described above, the structure of the pixel P applied to the light emitting display apparatus according to an embodiment of the invention may have the structure illustrated in FIG. 2 or the structure illustrated in FIG. 8.

In this case, the structure of the pixel P illustrated in FIG. 8 is similar to the structure of the pixel P illustrated in FIG. 2, so the driving method of the light emitting display apparatus including the pixel P illustrated in FIG. 8 is similar to the driving method of the light emitting display apparatus including the pixel P illustrated in FIG. 2.

Therefore, hereinafter, details which are the same as or similar to those described with reference to FIGS. 1 to 7 are omitted or briefly described.

The pixel P provided in the light emitting display panel 100 may include a pixel driving circuit PDC, which includes four transistors T1 to T4 and a storage capacitor Cst, and a light emitting device ED electrically connected to the pixel driving circuit PDC, as illustrated in FIG. 8.

The connection structure of the first transistor T1, the fourth transistor T4, the storage capacitor Cst, and the light emitting device ED is the same as the connection structure of the first transistor T1, the fourth transistor T4, the storage capacitor Cst, and the light emitting device ED described with reference to FIG. 2.

However, in the pixel P illustrated in FIG. 8, the gate of the second transistor T2 and the gate of the third transistor T3 are not electrically connected to each other.

For example, in order to prevent or reduce the second transistor T2 and the third transistor T3 from affecting each other, the gate of the second transistor T2 and the gate of the third transistor T3 may not be electrically connected to each other.

In this case, different scan signals are supplied to the gate of the second transistor T2 and the gate of the third transistor T3.

For example, the power scan signal EL_SCAN may be supplied to the gate of the second transistor T2, and the data scan signal DATA_SCAN may be supplied to the gate of the third transistor T3.

In this case, the data scan signal DATA_SCAN supplied to the gate of the third transistor T3 and the compensation scan signal COMP_SCAN supplied to the gate of the fourth transistor T4 may be the same signals as illustrated in FIG. 9.

In this case, the type of the second transistor T2 and the type of the third transistor T3 are different from each other.

For example, as illustrated in FIG. 8, each of the first transistor T1, the third transistor T3, and the fourth transistor T4 may be an N-type transistor, and the second transistor T2 may be a P-type transistor.

In this case, each of the first transistor T1, the third transistor T3, and the fourth transistor T4 may be an oxide thin film transistor, and the second transistor T2 may be a low-temperature polysilicon thin film transistor (LTPS TFT).

The light emitting device ED may include a first electrode, which receives a first voltage EVDD through the second transistor T2 and the first transistor T1, a second electrode electrically connected to a line to which the second voltage EVSS is supplied, and a light emitting layer provided between the first electrode and the second electrode. The first electrode may be an anode, and the second electrode may be a cathode. The first electrode may be electrically connected to the first terminal of the first transistor T1 and the second terminal of the fourth transistor T4.

When the pixel driving circuit PDC is formed in the structure illustrated in FIG. 8, the magnitude of the current flowing to the light emitting device ED may be proportional to the square of the voltage obtained by subtracting the threshold voltage of the light emitting device ED from the data voltage Vdata.

To this end, the operation as described with reference to FIGS. 3 to 7 can be performed.

First, in a previous frame period A0, light having a luminance corresponding to a data voltage Vdata supplied in the (k−1)th frame is output from the light emitting device ED.

In this case, a gate voltage Vg of the first transistor T1 may include the data voltage Vdata supplied in the (k−1)th frame.

Next, when a kth frame begins, a compensation and writing period A1 begins.

In the compensation and writing period A1, a threshold voltage of the first transistor T1 is compensated, and the data voltage Vdata can be charged in the gate of the first transistor T.

Here, compensating the threshold voltage of the first transistor T1 may mean that the threshold voltage of the first transistor T1 is charged in the gate of the first transistor T1.

Therefore, in the compensation and writing period A1, the data voltage Vdata supplied through the data line DL may be charged in the gate of the first transistor T1 through the third transistor T3, the first transistor T1, and the fourth transistor T4.

In this case, the gate of the first transistor T1 may be charged with a voltage obtained by subtracting the high level VEM_H of the light emission scan signal EM_SCAN from the sum of the threshold voltage of the first transistor T1 and the data voltage supplied to the gate of the first transistor T1 through the third transistor T3, the first transistor T1, and the fourth transistor T4.

Because the gate of the first transistor T1 and the first terminal (hereinafter, simply referred to as a “source”) of the first transistor T1 are connected through the fourth transistor T4, the source voltage Vs of the first transistor T1 can be the same as the gate voltage Vg of the first transistor T1.

In the compensation and writing period A1 during which the threshold voltage of the first transistor T1 and the data voltage Vdata are charged in the gate of the first transistor T1, as illustrated in FIG. 9, the phase of the power scan signal EL_SCAN supplied to the gate of the second transistor T2 may be the same as the phase of the data scan signal DATA_SCAN, and the phase of the power scan signal EL_SCAN may be opposite to the phase of the light emission scan signal EM_SCAN supplied to the first terminal of the storage capacitor Cst.

Because the data scan signal DATA_SCAN and the compensation scan signal COMP_SCAN are the same signal, in the compensation and writing period A1, the phase of the compensation scan signal COMP_SCAN may be opposite to the phase of the light emission scan signal EM_SCAN supplied to the first terminal of the storage capacitor Cst, as illustrated in FIG. 9.

Next, a holding period A2 of the kth frame begins.

In the holding period A2, the voltage charged in the gate of the first transistor T1 during the compensation and writing period Almay be maintained.

In the holding period A2 between the compensation and writing period A1 and the light emitting period A3 during which light is output from the light emitting device ED, the phase of the data scan signal DATA_SCAN and the phase of the light emission scan signal EM_SCAN may be the same.

In addition, because the data scan signal DATA_SCAN and the compensation scan signal COMP_SCAN are the same signal, the phase of the compensation scan signal COMP_SCAN may be the same as the phase of the light emission scan signal EM_SCAN in the holding period A2, as illustrated in FIG. 9.

Finally, a light emitting period A3 of the kth frame begins.

As described above with reference to [Equation 1] to [Equation 3], according to the light emitting display apparatus according to an embodiment of the invention, the magnitude of the current Ioled flowing to the light emitting device ED during the light emitting period A4 is not related to the threshold voltage Vth of the first transistor T1 and may be determined by the data voltage Vdata.

Therefore, even if the light emitting display apparatus according to an embodiment of the invention is used for a long time and the first transistor T1 is deteriorated, the luminance of light output from the light emitting device ED may be changed only by the data voltage Vdata and is not affected by the threshold voltage Vth of the first transistor T1.

Accordingly, according to the light emitting display apparatus according to an embodiment of the invention, the quality of the light emitting display apparatus may be maintained for a long time.

In the light emitting period A3 during which light is output from the light emitting device ED, the phase of the power scan signal EL_SCAN and the phase of the data scan signal DATA_SCAN may be opposite to the phase of the light emission scan signal EM_SCAN.

Also, because the data scan signal DATA_SCAN and the compensation scan signal COMP_SCAN are the same signal, the phase of the compensation scan signal COMP_SCAN may be opposite to the phase of the light emission scan signal EM_SCAN, as illustrated in FIG. 9.

In particular, according to the pixel P illustrated in FIG. 8, because the second transistor T2 and the third transistor T3 are independently driven, a phenomenon in which the second transistor T2 and the third transistor T3 are electrically connected at the moment may be prevented.

In addition, in order to reliably prevent or reduce a phenomenon in which the second transistor T2 and the third transistor T3 are electrically connected at the moment, in the light emitting display apparatus according to an embodiment of the invention, as illustrated in FIG. 9, when the compensation and lighting period A1 begins, the second transistor T2 is turned off by the power scan signal EL_SCAN, and after a predetermined period has elapsed, the third transistor T3 may be turned on by the data scan signal DATA_SCAN.

Also, when the compensation and writing period A1 ends, the third transistor T3 is turned off by the data scan signal DATA_SCAN, and after a predetermined period has elapsed, the second transistor T2 may be turned on by the power scan signal EL_SCAN.

The light emitting display apparatus according to embodiments of the invention may be applied to all electronic devices requiring a display of an image. For example, the light emitting display apparatus according to the invention may be applied to a virtual reality (VR) device, an augmented reality (AR) device, a mobile device, a video phone, a smart watch, a watch phone, or a wearable device, foldable device, rollable device, bendable device, flexible device, curved device, electronic notebook, e-book, PMP (portable multimedia player), PDA (personal digital assistant), MP3 player, mobile medical device, desktop PC, laptop PC, netbook computer, workstation, navigation, car navigation, vehicle display devices, televisions, wall paper display devices, signage devices, game devices, laptops, monitors, cameras, camcorders, and home appliances.

In the light emitting display apparatus according to embodiments of the invention, the threshold voltage of the driving transistor may be compensated by using four transistors provided in the pixel.

Also, in the light emitting display apparatus according to embodiments of the invention, the number of transistors provided in the pixel may be minimized or reduced, thereby increasing a PPI (Pixel-Per-Inch) of the display, so a clearer image can be displayed through the light emitting display apparatus.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A light emitting display apparatus comprising:
a light emitting device;
a first transistor including a first terminal electrically connected to a first terminal of the light emitting device and a second terminal;
a second transistor electrically connected between the second terminal of the first transistor and a first voltage line to which a first voltage is supplied;
a third transistor electrically connected between the second terminal of the first transistor and a data line to which a data voltage is supplied;
a storage capacitor electrically connected between a gate of the first transistor and a line to which a light emission scan signal is supplied; and
a fourth transistor including a first terminal electrically connected to the gate of the first transistor and a second terminal electrically connected to the first terminal of the light emitting device.

2. The light emitting display apparatus of claim 1, wherein a type of the second transistor and a type of the third transistor are different from each other.

3. The light emitting display apparatus of claim 1, wherein each of the first transistor, the third transistor, and the fourth transistor is an N-type transistor, and the second transistor is a P-type transistor.

4. The light emitting display apparatus of claim 1, wherein a current flowing through the light emitting device is proportional to a square of a voltage obtained by subtracting a threshold voltage of the light emitting device from the data voltage.

5. The light emitting display apparatus of claim 1, wherein a gate of the second transistor and a gate of the third transistor are electrically connected to each other.

6. The light emitting display apparatus of claim 1, wherein a power scan signal supplied to a gate of the second transistor, a data scan signal supplied to a gate of the third transistor, and a compensation scan signal supplied to a gate of the fourth transistor are the same signals.

7. The light emitting display apparatus of claim 6, wherein, in a compensation and writing period during which a threshold voltage of the first transistor and the data voltage are charged in the gate of the first transistor, a phase of the power scan signal is opposite to a phase of a light emission scan signal supplied to a first terminal of the storage capacitor.

8. The light emitting display apparatus of claim 7, wherein, in a light emitting period during which light is emitted from the light emitting device, a phase of the power scan signal is opposite to a phase of the light emission scan signal.

9. The light emitting display apparatus of claim 8, wherein, during a holding period between the compensation and writing period and the light emitting period, a phase of the power scan signal and a phase of the light emission scan signal are the same.

10. The light emitting display apparatus of claim 1, wherein a gate of the second transistor and a gate of the third transistor are not electrically connected to each other.

11. The light emitting display apparatus of claim 10, wherein a data scan signal supplied to a gate of the third transistor and a compensation scan signal supplied to a gate of the fourth transistor are the same signals.

12. The light emitting display apparatus of claim 11, wherein, in a compensation and writing period during which a threshold voltage of the first transistor and the data voltage are charged in the gate of the first transistor, a phase of a power scan signal supplied to the gate of the second transistor is the same as a phase of the data scan signal, and a phase of the power scan signal is opposite to a phase of a light emission scan signal supplied to a first terminal of the storage capacitor.

13. The light emitting display apparatus of claim 12, wherein, in a light emitting period during which light is output from the light emitting device, a phase of the power scan signal and a phase of the data scan signal both are opposite to a phase of the light emission scan signal.

14. The light emitting display apparatus of claim 12, wherein, in a holding period between the compensation and writing period and a light emitting period during which light is output from the light emitting device, a phase of the data scan signal and a phase of the light emission scan signal are the same.

15. The light emitting display apparatus of claim 12, wherein, when the compensation and writing period begins, the second transistor is turned off by the power scan signal, and after a predetermined period elapses, the third transistor is turned on by the data scan signal.

16. The light emitting display apparatus of claim 15, wherein, when the compensation and writing period ends, the third transistor is turned off by the data scan signal, and after a predetermined period elapses, the second transistor is turned on by the power scan signal.
